(19) United States
(12) Patent Application Publication
(10) Pub. No.: US 2012/0313118 A1
(43) Pub. Date: Dec. 13, 2012

(54) ACTIVE-MATRIX ORGANIC LIGHT-EMITTING DIODE DISPLAY DEVICE WITH SHORT PROTECTION

(75) Inventors: Ihor Wacyk, Hopewell Junction, NY (US); Amalkumar P. Ghosh, Hopewell Junction, NY (US); Ilyas I. Khayrullin, Hopewell Junction, NY (US); Tariq Ali, Hopewell Junction, NY (US)

(73) Assignee: eMagin Corporation, Hopewell Junction, NY (US)

(21) Appl. No.: 13/487,376

(22) Filed: Jun. 4, 2012

Related U.S. Application Data
(60) Provisional application No. 61/495,763, filed on Jun. 10, 2011.

(51) Int. Cl. H01L 27/32

(52) U.S. Cl. 257/88; 257/E27.119; 257/40

(57) ABSTRACT

An active-matrix OLED display device, which reduces the adverse effects of short circuits across OLED devices in a densely packed array by having a thin-film resistive layer integrated in series with the OLED device. The OLED device includes a substrate, and first and second pixels situated proximate each other on the substrate. The first pixel comprises an OLED and means for preventing a failure of the first pixel due to a short from affecting the operation of the second pixel. The preventing means includes a resistor electrically connected in series with the OLED of the first pixel. The resistor is in the form of a thin-film resistive layer. The first pixel includes an anode, wherein the thin-film resistive layer is situated adjacent the anode. The anode and the thin-film resistive layer have substantially the same dimensions and are formed simultaneously.

### CROSS-REFERENCE TO RELATED APPLICATION

This application claims the benefit of provisional patent application Ser. No. 61/495,763 filed in the United States Patent and Trademark Office on Jun. 10, 2011.

### BACKGROUND OF THE INVENTION

1. Field of the Invention

This invention relates generally to organic light-emitting diodes (OLEDs), and more particularly, to an active-matrix organic light-emitting diode (AMOLED) display device, which reduces the adverse effects of short circuits across OLED devices in a densely packed array by having a patterned thin-film resistive layer integrated in series with the OLED device.

2. Description of the Related Art

An OLED device typically includes a stack of thin layers formed on a substrate. A light-emitting layer of a luminescent organic solid, as well as adjacent semiconducting layers, is sandwiched between a cathode and an anode. The light-emitting layer may be selected from any of a multitude of fluorescent and phosphorescent organic solids. Any of the layers, and particularly the light-emitting layer, also referred to herein as the organic electroluminescent (EL) layer, emissive layer or the organic emissive layer, may consist of multiple sub-layers.

In an OLED device, an electric current is applied across the device, causing negatively charged electrons to inject into the organic material(s) from the cathode. Positive charges, typically referred to as holes, inject from the anode. When properly constructed, the injected electrons and holes recombine in the light-emitting layer within the organic EL layer and the recombination of these charge carriers cause light to emit from the device.

As can be appreciated, OLED devices are prone to shorting because of the small separation between the anode and the cathode. Pinholes, steps, cracks or roughness in layers create defective areas. These defects create direct contact between the anode and cathode layers or cause the organic layer thickness to be very small. The defects create pathways between the electrodes through the light emitting layer of the OLED that have low or no resistance, resulting in a short across the device. In multi-pixel designs as disclosed in the present invention, shorting defects can result in dead pixels that do not emit light. Various failures of a single pixel can spread to affect many other pixels in both current-driven and voltage driven designs. For example, in a current driven pixel cell an OLED short will result in a stuck-off pixel and a large current flowing through the p-channel protection diode tied between the ground and the anode. For a low-ohmic short, this current can be in the mA range for a single device. Current spreading in the cathode layer will result in a voltage drop around the dead pixel that will reduce the luminance of neighboring pixels, especially at low grayscales. A high total dark current resulting from many shorted diodes will also reduce the display luminance since this current is diverted from the array.

In a voltage-driven pixel an OLED short will result in a very high current when the drive transistor is on. This occurs because the current limiting action of the OLED will be absent. This can result in an additional negative effect, whereby the neighboring pixel circuits are turned off, resulting in a large area of dark pixels surrounding the stuck-off pixel.

It is, therefore, a primary object of the present invention to reduce the adverse effects of short circuits across OLED devices in a densely packed active-matrix OLED display array.

It is another object of the present invention to provide a patterned thin-film resistive layer integrated in series with the OLED device for preventing the failure caused by a short across an OLED from adversely affecting the operation of neighboring OLEDs.

It is another object of the present invention to provide a series limiting device, wherein the thin-film resistive layer has the advantage of consuming no additional pixel area.

It is another object of the present invention to provide individual resistors in series with each pixel OLED, which is accomplished by patterning both the anode conductive area and the thin-film resistive layer simultaneously.

It is another object of the present invention to prevent a yield loss due to a limited number of OLED shorts by preventing spreading effect of a stuck-on pixel to neighboring pixels.

It is another object of the present invention to limit the presence of dark current to prevent a reduction in luminance.

### BRIEF SUMMARY OF THE INVENTION

In accordance with one aspect of the present invention, an active-matrix organic light-emitting diode display device is presented, which reduces the adverse effects of short circuits across OLED devices in a densely packed active-matrix OLED display array.

In this embodiment, the active-matrix OLED display pixel comprises an OLED and a thin-film resistive layer connected in series with the OLED. The active-matrix OLED display pixel may further include an anode. The thin-film resistive layer is preferably situated adjacent the anode. The anode and the thin-film resistive layer of the AMOLED display pixel preferably have substantially the same dimensions and may be formed simultaneously.

In accordance with an additional embodiment, an active-matrix OLED display is presented which includes a substrate, and first and second pixels situated proximate each other on the substrate. In this display, the first pixel includes an OLED and means for preventing a failure of the first pixel due to a short from affecting the operation of the second pixel. The preventing means of the display includes a resistor electrically connected in series with the OLED of the first pixel.

The resistor of the display is in the form of a thin-film resistive layer. The OLED of the first pixel of the display includes an anode. Here, the thin-film resistive layer is preferably situated adjacent the anode. The anode and the thin-film resistive layer have substantially the same dimensions and may be formed simultaneously. Preferably, the substrate of the display may be silicon.

In accordance with an additional embodiment, an active-matrix OLED display pixel is presented which includes an OLED and a thin-film resistive layer connected in series with the OLED. The OLED includes an anode such that the thin-film resistive layer is situated adjacent the anode. The anode and the thin-film resistive layer have substantially the same dimensions and are formed simultaneously.

### BRIEF DESCRIPTION OF THE SEVERAL VIEWS OF THE DRAWINGS

To these and to such other objects that may hereinafter appear, the present invention relates to an active-matrix organic light-emitting diode (AMOLED) display device having a patterned thin film resistive layer integrated in series with the organic light-emitting diode (OLED) device which reduces the adverse effects of short circuits across OLED devices in a densely packed array, and is described in detail in the following specification and recited in the annexed claims, taken together with the accompanying drawings, in which like numerals refer to like parts in which:

FIG. 1 is a schematic cross-sectional view of a conventional OLED display device having a thin-film resistive layer in accordance with the preferred embodiment; and

FIG. 2 is a schematic diagram of a pixel voltage drive circuit of the present invention wherein the resistor is in series with the OLED.

To the accomplishment of the above and related objects the invention may be embodied in the form illustrated in the accompanying drawings. Attention is called to the fact, however, that the drawings are illustrative only. Variations are contemplated as being part of the invention, limited only by the scope of the claims.

### DETAILED DESCRIPTION OF THE INVENTION

The present invention is directed to an active-matrix organic light-emitting diode (AMOLED) display device 100, which eliminates adverse effects of short circuits across OLEDs in a densely packed array by preventing failure of a single pixel from affecting any neighboring pixels.

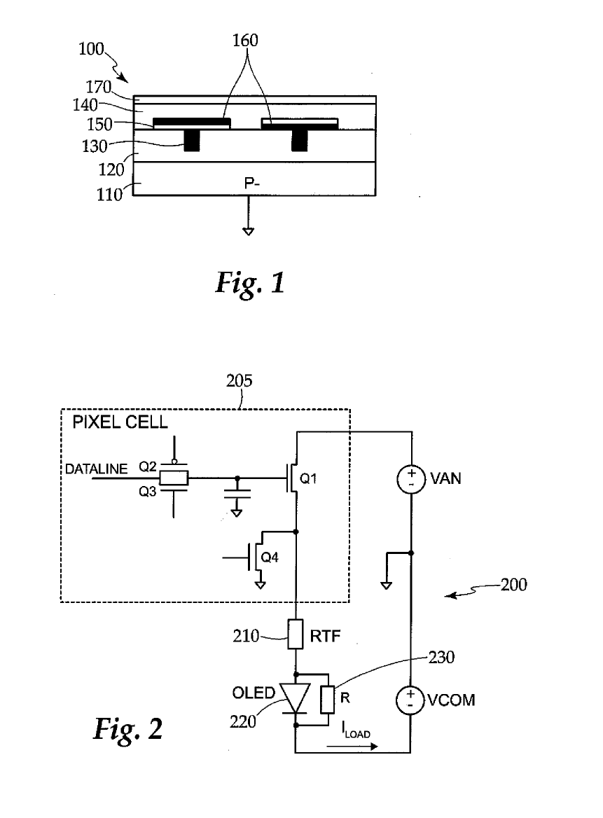

FIG. 1 illustrates a cross-sectional view of the active-matrix OLED display device 100 according to one embodiment of the present invention, wherein an OLED layer 140 includes an anode conductive area 120. The OLED display device 100 includes a substrate 110, preferably silicon, and a planarized insular layer 120 disposed over the substrate 110. The planarized insular layer 120 includes at least one top via 130. An organic EL layer or OLED layer 140 is disposed over the planarized insular layer 120, and an anode conductive area 150 corresponding to each color subpixel is disposed within the organic EL layer 140 adjacent each via 130. The OLED layer 140 is sandwiched between the planarized insular layer 120 and a cathode layer 170 disposed thereon. Here, the anode conductive area 150 within the OLED layer 140 is in contact with the top via 130.

A short reduction layer (SRL) in the form of a thin-film resistive layer 160 is patterned and layered adjacent the anode conductive area 150 and is predetermined to have a thickness and resistivity sufficient to resist the leakage current and the associated loss of emission and negative interaction with neighboring pixels due to shorting defects. The anode conductive area 150 and the thin-film resistive layer 160 preferably have substantially the same dimensions and may be formed simultaneously, such that the thin-film resistive layer 160 is in series with each OLED.

The anode conductive area 150 is illustrated in the present view wherein the thin-film resistive layer 160 is shown thereon. For purposes of example, FIG. 1 illustrates the thin-film resistive layer 160 when located above or below the anode conductive area 150. Patterning both the anode conductive area 150 and the thin-film resistive layer 160 simultaneously will leave individual resistors in series with each pixel OLED.

The resistivity of the thin-film resistive layer 160 is determined by the thickness of the thin-film resistive layer 160 and the size of the anode conductive area 150, such that the thin-film resistive layer 160 provides a series resistance of about 1 Mohm per pixel. Unlike other series limiting devices, the thin-film resistive layer 160 of the present device 100 has the advantage of consuming no additional pixel area.

FIG. 2 is a schematic drawing illustrating a pixel voltage drive circuit 200 of the active-matrix OLED display device 100, wherein resistor 210 is in series with the OLED 220 of the first pixel 205 to limit current through an OLED in case of a short. In the preferred embodiment a first and second pixel are situated proximate each other on the substrate. The first pixel 205 includes the OLED and means for preventing failure of the first pixel 205 from affecting the operation of the second pixel. The preventing means is in the form of the resistor 210. A predetermined, and properly chosen, value for the resistor 210 will not have a significant effect on the normal operation of a good OLED 220, but can limit the current in a shorted device to a safe value that prevents any interaction with neighboring pixels.

For example, peak-operating current for a normal pixel is less than 15 nA, corresponding to 40 mA/cm2 for a 12×4 micron pixel size. When the series resistor 210 is equal to 1 Mohm it results in a drop, of 15 mV in the voltage bias to the pixel in a worst-case scenario, resulting in a negligible impact to the luminance of the pixel. On the other hand, the same resistor 210 limits the current for a 0 ohm OLED short 230 to less than 10 micro amps, nearly a thousand times less than that for an unprotected pixel.

In conclusion, herein is presented an active-matrix OLED display device, which prevents the failure caused by a short across an OLED from adversely affecting the operation of neighboring OLEDs. The invention is illustrated by example in the drawing figures, and throughout the written description. It should be understood that numerous variations are possible, while adhering to the inventive concept. Such variations are contemplated as being a part of the present invention.

While only a limited number of preferred embodiments of the present invention have been disclosed for purposes of illustration, it is obvious that many modifications and variations could be made thereto. It is intended to cover all of those modifications and variations, which fall within the scope of the present invention as defined by the following claims.

We claim:

1. An active-matrix OLED display pixel comprising an OLED and a thin-film resistive layer connected in series with the OLED.

2. The active-matrix OLED display pixel of claim 1, wherein said OLED of said pixel comprises an anode and wherein said thin-film resistive layer is situated adjacent said anode.

3. The active-matrix OLED display pixel of claim 2, wherein said anode and said thin-film resistive layer have substantially the same dimensions.

4. The active-matrix OLED display pixel of claim 2, wherein said anode and said thin-film resistive layer are formed simultaneously.

5. An active-matrix OLED display comprising a substrate, first and second pixels situated proximate each other on said substrate, said first pixel comprising an OLED and means for preventing a failure of said first pixel due to a short from affecting the operation of said second pixel, said preventing means comprising a resistor electrically connected in series with said OLED of said first pixel.

6. The display of claim 5, wherein said resistor comprises a thin-film resistive layer.

7. The display of claim 6, wherein said OLED of said first pixel comprises an anode and wherein said thin-film resistive layer is situated adjacent said anode.

8. The display of claim 6, wherein said anode and said thin-film resistive layer have substantially the same dimensions.

9. The display of claim 6, wherein said anode and said thin-film resistive layer are formed simultaneously.

10. The display of claim 5, wherein said substrate is silicon.

11. An active-matrix OLED display pixel comprising an OLED and a thin-film resistive layer connected in series with the OLED, wherein said OLED includes an anode such that said thin-film resistive layer is situated adjacent said anode, and wherein said anode and said thin-film resistive layer have substantially the same dimensions and are formed simultaneously.
